(19) United States
(12) Patent Application Publication
(10) Pub. No.: US 2023/0197896 A1
(43) Pub. Date: Jun. 22, 2023

(54) METHOD TO IMPROVE THE PERFORMANCE OF GALLIUM-CONTAINING LIGHT-EMITTING DEVICES

(71) Applicant: The Regents of the University of California, Oakland, CA (US)

(72) Inventors: Matthew S. Wong, Santa Barbara, CA (US); Jordan M. Smith, Goleta, CA (US); Steven P. DenBaars, Goleta, CA (US)

(73) Assignee: The Regents of the University of California, Oakland, CA (US)

(21) Appl. No.: 17/768,182

(22) PCT Filed: Oct. 30, 2020
(86) PCT No.: PCT/US2020/058234

§ 371 Date: Apr. 11, 2022

Related U.S. Application Data
(60) Provisional application No. 62/927,859, filed on Oct. 30, 2019.

(51) Int. Cl. H01L 33/32; H01L 33/24

(52) U.S. Cl. CPC H01L 33/32; H01L 33/24; H01L 33/0062

(57) ABSTRACT

Gallium-containing semiconductor layers are grown on a substrate, followed by dry etching of the gallium-containing semiconductor layers during fabrication of a device. After the dry etching, surface treatments are performed to remove damage from the sidewalls of the device. After the surface treatments, dielectric materials are deposited on the sidewalls of the device to passivate the sidewalls of the device. These steps result in an improvement in forward current-voltage characteristics and reduction in leakage current of the device, as well as an enhancement of light output power and efficiency of the device.

### CROSS REFERENCE TO RELATED APPLICATIONS

This application claims the benefit under 35 U.S.C. Section 119(e) of the following co-pending and commonly-assigned application:

U.S. Provisional Application Serial No. 62/927,859, filed on Oct. 30, 2019, by Matthew S. Wong, Jordan M. Smith and Steven P. DenBaars, entitled “METHOD TO IMPROVE THE PERFORMANCE OF GALLIUM-CONTAINING LIGHT-EMITTING DEVICES,” attorneys’ docket number G&C 30794.0754USP1 (UC 2020-086-1);

which application is incorporated by reference herein.

### BACKGROUND OF THE INVENTION

### 1 Field of the Invention

This invention relates generally to light emitting diodes (LEDs), and more specifically, to a method to improve the performance of gallium-containing LEDs.

### 2 Description of the Related Art

In recent years, the developments of displays with superior resolution and color gamut have gained significant research attention. Micro-sized LEDs (also referred to as micro-LEDs or µLEDs) are considered as the most promising display technology for next-generation display applications. However, there are challenges required to be resolved before applying this technology for commercial production.

Among all the challenges, the material choice for the red µLEDs is one of the main problems for µLED displays. For full-color displays, red (~630 nm), green (~525 nm), and blue (~480 nm) colors are required. Highly efficient blue and green light emitting µLEDs using the InGaN material system have been demonstrated and are commercially available, yet high performance red light emitting LEDs using the InGaN material system have not been developed and are very difficult to realize due to material reasons.

On the other hand, conventional III-V semiconductor materials, namely the AlGaInP/GaAs material systems, have been employed as mature red emitters for a variety of commercial usages. The AlGaInP devices operate well in large dimensions, but efficiency decreases dramatically as the device shrinks, since the AlGaInP material system has a high minority carrier diffusion length that causes issues such as leakage current and non-radiative recombination.

Thus, there is a need in the art for improved methods for fabricating AlGaInP-based µLEDs. The present invention satisfies this need.

### SUMMARY OF THE INVENTION

The present invention discloses a method a method to improve the performance of gallium-containing LEDs. Gallium-containing semiconductor layers are grown on a substrate, followed by dry etching of the gallium-containing semiconductor layers during fabrication of a device. After the dry etching, surface treatments are performed to remove damage from the sidewalls of the device. After the surface treatments, dielectric materials are deposited on the sidewalls of the device to passivate the sidewalls of the device. These steps result in an improvement in forward current-voltage characteristics and reduction in leakage current of the device, as well as an enhancement of light output power and efficiency of the device.

### BRIEF DESCRIPTION OF THE DRAWINGS

FIG. 1 shows a schematic of a semiconductor material grown on the substrate.

FIG. 2 shows a schematic of a semiconductor material, including n-type doped, active and p-type doped layers.

FIG. 3 shows a diagram of the sidewall profile of a device after a nitrogen plasma treatment.

FIGS. 4 and 5 show forward current-voltage characteristics from 0 to 3.5 V and from -4 to 3.5 V of 20×20 µm² AlGaInP µLEDs.

FIGS. 6 and 7 present light output power and efficiency curves of 100×100 and 20×20 µm² AlGaInP µLEDs.

FIGS. 8 and 9 demonstrate leakage current density and efficiency for different device dimensions with different sidewall passivation techniques.

FIG. 10 is a flowchart of the process steps of the invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

In this invention, inorganic semiconductor materials are grown on a substrate, where the inorganic semiconductor material comprised of group III and group V elements with a chemical formula of AlₓGa_{y}In_{z}NᵥP_{w}Asᵤ where 0 ≤ x ≤ 1, 0 ≤ y ≤ 1,0 ≤ z ≤ 1, 0 ≤ v ≤ 1, 0 ≤ w ≤ 1, 0 ≤ u ≤ 1, v + w + u = 1, and x + y + z = 1. The substrate used can be optically transparent, semi-transparent, or opaque, and can be electrically conductive, semi-insulative, or insulative.

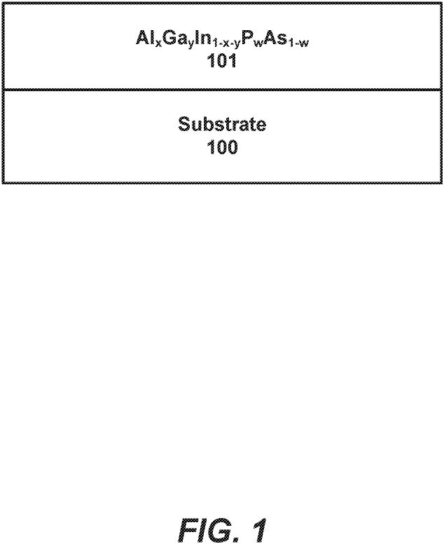

FIG. 1 shows a schematic of semiconductor material comprised of a substrate 100 and AlₓGa_{y}In_{1-x-y}P_{w}As_{1-w} 101 grown on the substrate 100.

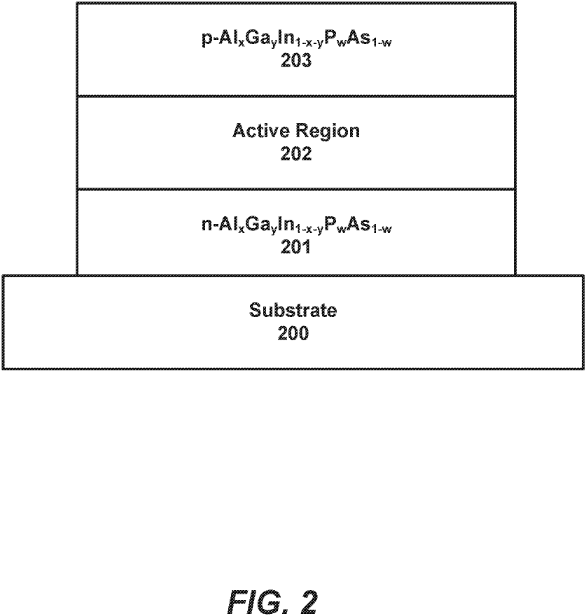

FIG. 2 shows a schematic of semiconductor material comprised of a substrate 200, n-type doped AlₓGa_{y}In_{1-x-y}P_{w}As_{1-w} 201 grown on the substrate 200, followed by growth of an active region 203 and p-type doped AlₓGa_{y}In_{1-x-y}P_{w}As_{1-w} 204.

Plasma-based dry etching is used to define the light-emitting area of the semiconductor material, also known as a mesa, by etching through the active region where light is emitted. After the etching step, the semiconductor material is sent to a vacuum chamber for sidewall treatment, wherein the vacuum chamber has the abilities of etching and deposition.

The semiconductor material can be sent to an etch chamber if the semiconductor material is exposed to ambient conditions after the mesa etching, since oxygen serves as non-radiative sites of the semiconductor material. In the etch chamber, a thin layer of the semiconductor material, on the order of nanometer scale, can be removed by low-power dry etching to eliminate the presence of oxygen atoms on exposed surfaces. This etching step further improves device performance.

The surface of the etched semiconductor material is then treated with alternating pulse cycles of trimethyl aluminum (TMA) and nitrogen/hydrogen plasma. This TMA and plasma surface treatment suppresses the effects of dry damage by removing non-radiative combination sites, reducing the surface sites, and filling the vacancies by nitrogen. The use of hydrogen plasma is not as critical as nitrogen plasma, because hydrogen plasma may react with other components on the substrate. The nitrogen plasma employed in the surface treatment is low power, such that the device is not damaged and there is no deposition from the metalorganic and plasma.

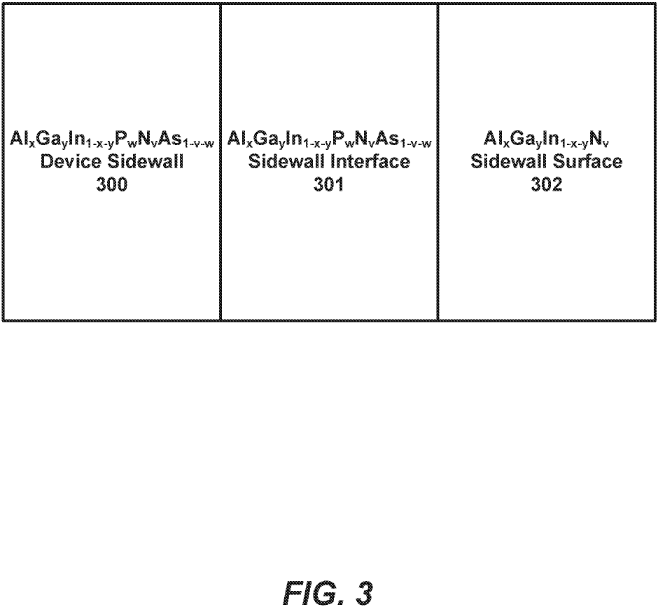

FIG. 3 shows a diagram of the sidewall profile of an AlGaInP device after the nitrogen plasma treatment, including an AlₓGa_{y}In_{1-x-y}P_{w}As_{1-w} device sidewall 300, AlₓGa_{y}In_{1-x-y}P_{w}NᵥAs_{1-v-w} sidewall interface 301 and AlₓGa_{y}In_{1-x-y}Nᵥ sidewall surface 302.

In additional to lessening the influences of sidewall damage from defining the mesa, the use of nitrogen plasma incorporates nitrogen atoms at the semiconductor material interface, and increases the bandgap at the surface and the interface for AlGaInP materials. Since nitride forms stronger chemical bonds with group III elements than phosphide and arsenide, the bandgap of nitride is greater than phosphide and arsenide, and thus the injected current is less able to reach to the sidewall after the nitrogen plasma treatment. The plasma approach is more attractive for AlGaInP device fabrication, because the AlGaInP material system has different reactivity and sensitivity to acidic or basic wet chemical treatment, and thus a plasma-based surface treatment is a more reliable and repeatable method.

In terms of nitride semiconductor material (e.g., AlₓGa_{y}In_{1-x-y}Nᵥ), nitrogen vacancies are generated after dry etching of the mesa and these nitrogen vacancies act as leakage paths and non-radiative recombination sites. By employing nitrogen plasma on the sidewall of the nitride semiconductor material, the nitrogen plasma compensates the nitrogen vacancies and enhances the device performances.

After the TMA and nitrogen plasma surface treatment, dielectric sidewall passivation is used to cover the surface of the semiconductor material with dielectric materials to terminate any surface recombination sites. The dielectric deposition method should cause no damage to the device while providing superior dielectric material quality. Atomic layer deposition (ALD) offers damage-free material deposition with excellent material quality.

The benefits of such sidewall treatments include better forward and reverse current-voltage device characteristics and enhancements in light output power. As a result, the efficiency of the small device also improves significantly with sidewall treatment.

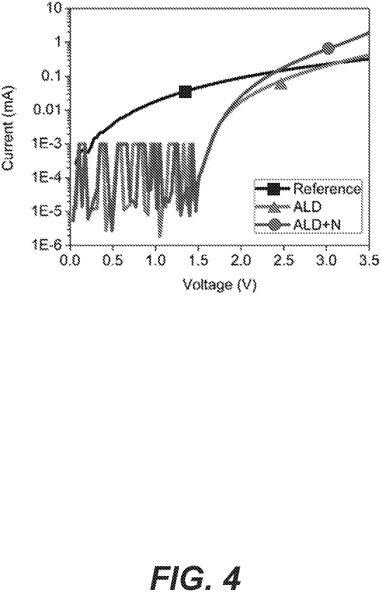

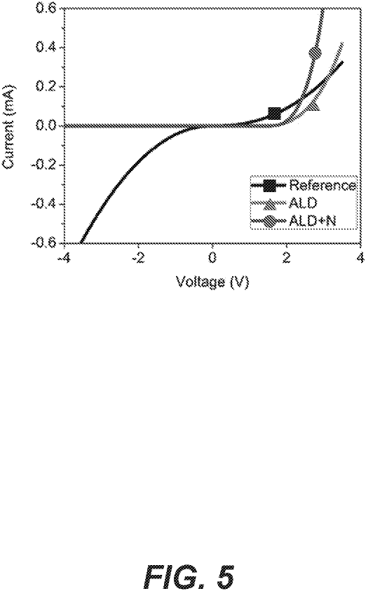

FIGS. 4 and 5 are graphs of Current (mA) vs. Voltage (V) that show the forward current-voltage characteristics from 0 to 3.5 V and from -4 to 3.5 V of 20×20 µm² AlGaInP µLEDs, wherein “Reference” refers to µLEDs without sidewall treatment, and “ALD” and “ALD+N” represent devices with Al₂O₃ sidewall passivation by ALD without and with TMA and nitrogen plasma surface treatments.

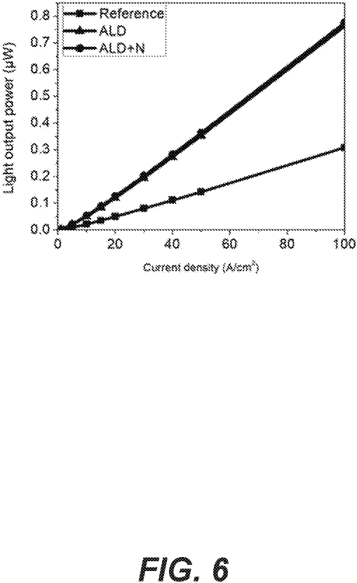

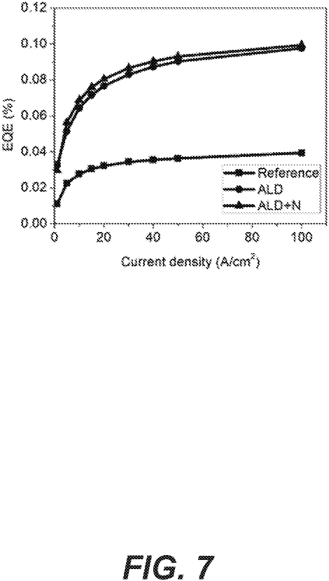

FIGS. 6 and 7 are graphs of Light Output Power (LOP) (µW) vs. Current Density (A/cm2) present the light output power and efficiency curves of 100×100 and 20×20 µm² AlGaInP µLEDs, wherein “Reference” refers to µLEDs without sidewall treatment, and “ALD” and “ALD+N” represent devices with Al₂O₃ sidewall passivation by ALD without and with TMA and nitrogen plasma surface treatments.

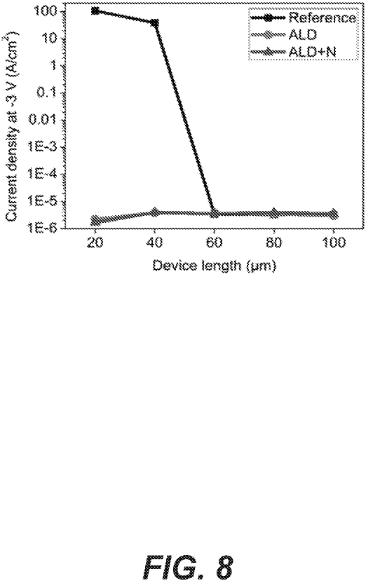

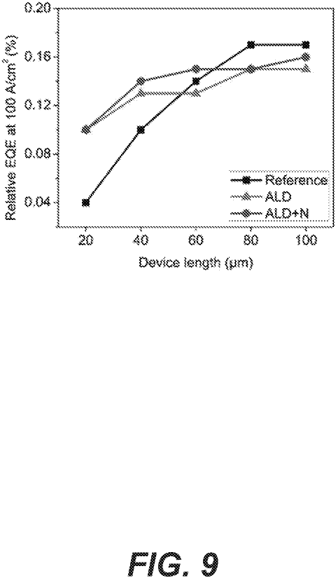

FIGS. 8 and 9 are graphs of Relative External Quantum Efficiency (EQE) at 100 A/cm² (%) vs. Device Length (µm), wherein “Reference” refers to µLEDs without sidewall treatment, and “ALD” and “ALD+N” represent devices with Al₂O₃ sidewall passivation by ALD without and with TMA and nitrogen plasma surface treatments. These graphs demonstrate the leakage current density and efficiency for different device dimensions with different sidewall passivation techniques.

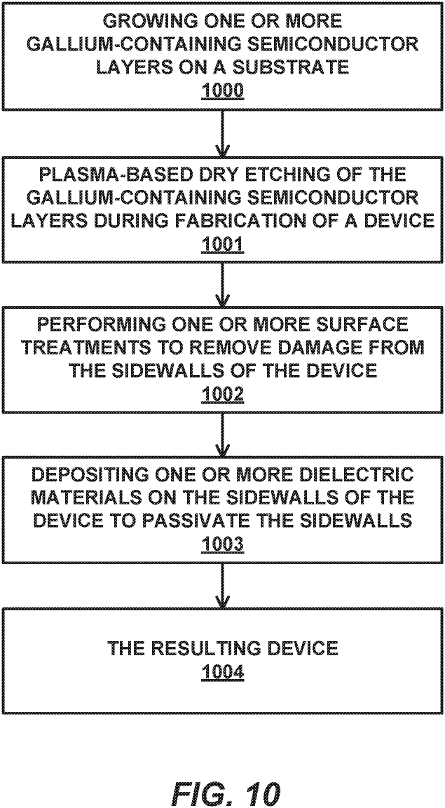

FIG. 10 is a flowchart of the process steps of this invention recited above.

Block 1000 represents the step of growing one or more gallium-containing semiconductor layers on a substrate. The gallium-containing semiconductor layers include one or more nitrogen, phosphorus, and/or arsenic atoms as counter atoms.

Block 1001 represents the step of plasma-based dry etching of the gallium-containing semiconductor layers during fabrication of a device.

Block 1002 represents the step of performing one or more surface treatments to remove damage or to alter a surface chemistry from sidewalls of the device, after the dry etching of the gallium-containing semiconductor layers. The surface treatments may comprise thermal-based or plasma-based nitridation, oxidation, and/or other surface chemistry modification techniques. In one or more embodiments, the surface treatments take place at a temperature above 25° C. In one or more embodiments, a source of plasma can be from gases, metalorganics, and/or other volatile chemicals. In one or more embodiments, the surface treatments are performed at a low power level to avoid physical deposition and damage to the device.

Block 1003 represents the step of depositing one or more dielectric materials on sidewalls of the device to passivate the sidewalls of the device, after the surface treatments of the sidewalls. In one or more embodiments, the dielectric deposition is conformal or uniform in covering the sidewalls. In one or more embodiments, the dielectric is deposited by atomic layer deposition, sputtering, plasma-enhanced chemical vapor deposition, and/or other chemical vapor deposition. In one or more embodiments, this step may further comprise a post-dielectric deposition to improve material quality and an interface between the dielectric materials and the sidewalls, such as annealing.

In one or more embodiments, material is removed at the device’s surface prior to the performing the surface treatment and depositing the dielectric materials.

Block 1004 represents a resulting device, wherein the performing and depositing steps result in an improvement in forward current-voltage characteristics and reduction in leakage current of the resulting device, as well as an enhancement of light output power and efficiency of the resulting device. In one or more embodiments, the device has a sidewall-perimeter to light-emitting area ratio larger than 0.04 µm⁻¹, and the device has one or more edges with a length of less than 80 µm.

### Benefits and Advantages

AlGaInP/GaAs system is a very mature material system for typical lighting applications, where the device size is large. Nevertheless, because of the inherent material properties, the main obstacles of using this material for µLEDs are the high leakage current and low energy efficiency at small device dimensions. This invention resolves the problems of leakage current and efficiency of AlGaInP µLEDs by employing device fabrication techniques that are easy to adopt. With low leakage current and good efficiency, AlGaInP µLEDs can be used as the red emitter in pLED displays.

### References

The following applications and publications are incorporated by reference herein:

1. U.S. Utility Pat. Application No. 16/757,920, filed on Apr. 21, 2020, by Matthew S. Wong, David Hwang, Abdullah Alhassan, and Steven P. DenBaars, entitled “REDUCTION IN LEAKAGE CURRENT AND INCREASE IN EFFICIENCY OF III-NITRIDE LEDS BY SIDEWALL PASSIVATION USING ATOMIC LAYER DEPOSITION,” attorney’s docket number 30794.0667USWO (UC 2018-256-2), which claims the benefit under 35 U.S.C. Section 365(c) of PCT International Patent Application No. PCT/US18/58362, filed on Oct. 31, 2018, by Matthew S. Wong, David Hwang, Abdullah Alhassan, and Steven P. DenBaars, entitled “REDUCTION IN LEAKAGE CURRENT AND INCREASE IN EFFICIENCY OF III-NITRIDE LEDS BY SIDEWALL PASSIVATION USING ATOMIC LAYER DEPOSITION,” attorney’s docket number 30794.0667WOU1 (UC 2018-256-2), which application claims the benefit under 35 U.S.C. Section 119(e) of U.S. Provisional Patent Application No. 62/580,287, filed on Nov. 1, 2017, by Matthew S. Wong, David Hwang, Abdullah Alhassan, and Steven P. DenBaars, entitled “REDUCTION IN LEAKAGE CURRENT AND INCREASE IN EFFICIENCY OF III-NITRIDE LEDS BY SIDEWALL PASSIVATION USING ATOMIC LAYER DEPOSITION,” attorney’s docket number 30794.0667USP1 (UC 2018-256-1).

2. PCT International Application Serial No. PCT/US19/59163, filed on Oct. 31, 2019, by Tal Margalith, Matthew S. Wong, Lesley Chan, and Steven P. DenBaars, entitled “MICRO-LEDS WITH ULTRA-LOW LEAKAGE CURRENT,” attorneys’ docket number G&C 30794.0707WOU1 (UC 2019-393-2), which application claims the benefit under 35 U.S.C. Section 119(e) of U.S. Provisional Application Serial No. 62/756,252, filed on Nov. 6, 2018, by Tal Margalith, Matthew S. Wong, Lesley Chan, and Steven P. DenBaars, entitled “MICRO-LEDS WITH ULTRA-LOW LEAKAGE CURRENT,” attorneys’ docket number G&C 30794.0707USP1 (UC 2019-393-1).

3. High Efficiency of III-Nitride Micro-Light-Emitting Diodes by Sidewall Passivation Using Atomic Layer Deposition, Optics Express, 26(16), 21324 (2018).

4. Size-independent Peak Efficiency of III-Nitride Micro-Light-Emitting Diodes using Chemical Treatment and Sidewall Passivation, Applied Physics Express, 12, 097004 (2019).

### Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1-15. (canceled)

16. A device, comprising:
one or more gallium-containing semiconductor layers grown on a substrate;
wherein the gallium-containing semiconductor layers are dry-etched gallium-containing semiconductor layers;
wherein sidewalls of the dry-etched gallium-containing semiconductor layers are surface-treated sidewalls to remove damage from or to alter a surface chemistry of the sidewalls; and
wherein one or more dielectric materials are deposited on the surface-treated sidewalls to passivate the surface-treated sidewalls.

17. (canceled)

18. The device of claim 16, wherein the gallium-containing semiconductor layers include one or more nitrogen, phosphorus, or arsenic atoms as counter atoms.

19. The device of claim 16, wherein the device has a sidewall perimeter to light emitting area ratio larger than 0.04 µm⁻¹.

20. The device of claim 16, wherein the device has one or more edges with a length of less than 80 µm.

21. The device of claim 16, wherein the dielectric materials are conformal or uniform in covering the surface-treated sidewalls.

22. The device of claim 16, wherein the dielectric materials are deposited by atomic layer deposition, sputtering, plasma-enhanced chemical vapor deposition, or other chemical vapor deposition.

23. The device of claim 16, further comprising a post-dielectric deposition to improve material quality and an interface between the dielectric materials and the sidewalls.

24. The device of claim 16, wherein the gallium-containing semiconductor materials comprise group III and group V elements with a chemical formula of AlₓGa_{y}In_{z}NᵥP_{w}Asᵤ where 0≤x≤1, 0≤y≤1, 0≤z≤1, 0≤v≤1, 0≤w≤1, 0≤u≤1.

25. A device, comprising:
a micro light emitting diode (microLED), comprising:
a mesa comprising gallium-containing semiconductor layers and having at least one of:
a top surface with an area of 10 micrometers squared or less, or at least one of a diameter, a largest width, or a largest dimension of 10 micrometers or less;
a side surface connected to the top surface; and
a dielectric deposited on the side surface to passivate a sidewall of the mesa.

26. The device of claim 25, wherein the gallium-containing semiconductor layers include one or more nitrogen, phosphorus, or arsenic atoms as counter atoms.

27. The device of claim 25, wherein the micro light emitting diode has a sidewall perimeter to light emitting area ratio larger than 0.04 µm⁻¹.

28. The device of claim 25, wherein the micro light emitting diode has one or more edges with a length of less than 80 µm.

29. The device of claim 25, wherein the dielectric is conformal or uniform in covering the sidewall.

30. The device of claim 25, wherein the dielectric is deposited by atomic layer deposition, sputtering, plasma-enhanced chemical vapor deposition, or other chemical vapor deposition.

31. The device of claim 25, further comprising a post-dielectric deposition to improve material quality and an interface between the dielectric and the sidewall.

32. The device of claim 25, wherein the gallium-containing semiconductor layers comprise group III and group V elements with a chemical formula of AlₓGa_{y}In_{z}NᵥP_{w}Asᵤ where 0≤x≤1, 0≤y≤1, 0≤z≤1, 0≤v≤1, 0≤w≤1, 0≤u≤1.
